(19) United States
(12) Patent Application Publication
(10) Pub. No.: US 2017/0349381 A1
(43) Pub. Date: Dec. 7, 2017

(54) APPARATUSES, SYSTEMS, AND METHODS FOR PROCESSING SEMICONDUCTOR COMPONENTS

(71) Applicant: HGST Netherlands B.V., Amsterdam (NL)

(72) Inventors: Jacey R. Beaucage, San Jose, CA (US); Glenn P. Gee, San Jose, CA (US); Trevor W. Olson, San Jose, CA (US); Darrick T. Smith, San Jose, CA (US)

(21) Appl. No.: 15/170,128

(22) Filed: Jun. 1, 2016

(51) Int. Cl. B65G 47/26; H01L 21/673

(52) U.S. Cl. CPC B65G 47/26; H01L 21/67333

(57) ABSTRACT

Described herein is an apparatus, for processing semiconductor components, includes support surfaces and flexible couplings. The support surfaces are parallel to a first direction and spaced apart from each other in a second direction, perpendicular to the first direction. Moreover, the support surfaces are translationally movable relative to each other in the second direction to increase a pitch between adjacent support surfaces from a first pitch to a second pitch. Each of the flexible couplings is between and fixed to respective adjacent ones of the support surfaces. The flexible couplings flex as the support surfaces translationally move relative to each other in the second direction.

### FIELD

This disclosure relates generally to processing semiconductor components, and more particularly to processing sliders for hard disk drives.

### BACKGROUND

Electronic devices, such as electronic data storage devices, including hard disk drives, are commonly used for storing and retrieving digital information. Some components of electrical devices, such as sliders having read/write heads, are made from semiconductor materials. Desirably, many semiconductor components are co-formed on a single wafer and then individually separated and further processed in subsequent manufacturing steps. Separating co-formed semiconductor components in a manner that promotes efficiency, accuracy, and lower costs can be challenging.

### SUMMARY

The subject matter of the present application has been developed in response to the present state of the art, and in particular, in response to the shortcomings of processes for manufacturing semiconductor components that have not yet been fully solved by currently available techniques. Accordingly, the subject matter of the present application provides apparatuses, systems, and methods for processing semiconductor components that overcome at least some of the above-discussed shortcomings of prior art techniques.

According to one embodiment, an apparatus, for processing semiconductor components, includes support surfaces and flexible couplings. The support surfaces are parallel to a first direction and spaced apart from each other in a second direction, perpendicular to the first direction. Moreover, the support surfaces are translationally movable relative to each other in the second direction to increase a pitch between adjacent support surfaces from a first pitch to a second pitch. Each of the flexible couplings is between and fixed to respective adjacent ones of the support surfaces. The flexible couplings flex as the support surfaces translationally move relative to each other in the second direction.

In one implementation, the apparatus further includes a linear actuator fixed to one of the support surfaces. The linear actuator is selectively operable to translationally move the support surfaces relative to each other in the second direction.

According to another implementation of the apparatus, adjacent support surfaces are co-movable in the second direction via the flexible coupling between and fixed to the adjacent support surfaces.

In some implementations of the apparatus, the support surfaces are translationally movable relative to each other in a third direction, opposite the second direction, to decrease the pitch from the second pitch to the first pitch. Adjacent support surfaces are co-movable in the third direction via the flexible coupling between and fixed to the adjacent support surfaces. The flexible couplings flex as the support surfaces translationally move relative to each other in the third direction. The flexible couplings can expand as support surfaces translationally move relative to each other in the second direction. In contrast, the flexible couplings can compress as support surfaces translationally move relative to each other in the third direction.

According to certain implementations, the apparatus also includes at least one locking element. The at least one locking element includes spacers having a third pitch between adjacent spacers, where the third pitch is equal to the second pitch. The at least one locking element is movable relative to the support surfaces to position respective spacers between adjacent support surfaces at the second pitch. The at least one locking element can be translationally movable in the first direction relative to the support surfaces to position respective spacers between adjacent support surfaces at the second pitch. Alternatively, the at least one locking element can be rotationally movable relative to the support surfaces to position respective spacers between adjacent support surfaces at the second pitch. For locking elements that are rotationally movable, the spacers of the at least one locking element are separated into groupings of spacers adjacent each other in the second direction along the at least one locking element, where each spacer of each grouping of spacers has a circumferential length different than each spacer of others of the groupings of spacers, and a circumferential length of each spacer of any grouping of spacers is greater than a circumferential length of each spacer of any adjacent grouping of spacers in the second direction.

In another embodiment, a system for processing semiconductor components includes a fixture and a first tray. The fixture includes a frame, support surfaces, and flexible couplings. The support surfaces are movably coupled to the frame, parallel to each other in a first direction, spaced apart from each other in a second direction, perpendicular to the first direction, and translationally movable relative to each other in the second direction to increase a pitch between adjacent support surfaces from a first pitch to a second pitch. Each of the flexible couplings is between and fixed to respective adjacent ones of the support surfaces. The flexible couplings flex as the support surfaces translationally move relative to each other in the second direction. The first tray includes receptacles that have a fourth pitch between adjacent receptacles. The fourth pitch is equal to the second pitch. The first tray is releasably coupleable to the frame.

According to some implementations of the system, the first tray further includes first apertures each formed in a respective one of the receptacles. The system may also include a first vacuum base that is relasably coupleable to the first tray and includes at least one fluid conduit communicatively coupled with the first apertures of the first tray when the first vacuum base is releasably coupled to the first tray. Additionally, the system can include a vacuum that is communicatively coupleable with the at least one fluid conduit of the first vacuum base and operable to draw air from the receptacles of the first tray via the first apertures of the first tray and the at least one fluid conduit of the first vacuum base when the vacuum is communicatively coupled with the at least one fluid conduit of the first vacuum base and the first vacuum base is releasably coupled to the first tray. The system can further include a second tray that includes receptacles having a fifth pitch between adjacent receptacles, where the fifth pitch is equal to the second pitch. The second tray is releasably coupleable to the first tray. The second tray can further include second apertures each formed in a respective one of the receptacles of the second tray. The system may additionally include a second vacuum base that is relasably coupleable to the second tray and includes at least one fluid conduit communicatively coupled with the second apertures of the second tray when the second vacuum base is releasably coupled to the second tray. The vacuum may be communicatively coupleable with the at least one fluid conduit of the second vacuum base and operable to draw air from the receptacles of the second tray via the second apertures of the second tray and the at least one fluid conduit of the second vacuum base when the vacuum is communicatively coupled with the at least one fluid conduit of the second vacuum base and the second vacuum base is releasably coupled to the second tray.

According to yet another embodiment, a method of processing semiconductor components includes coupling a row of semiconductor components on support surfaces, spaced at a first pitch between adjacent surfaces, such that the row of semiconductor components extends in a second direction and each semiconductor component of the row of adjoined semiconductor components is supported by a respective one of the support surfaces. The semiconductor components of the row of semiconductor components are adjoined. The support surfaces are parallel to each other in a first direction, perpendicular to the second direction, and spaced apart from each other in the second direction. The method also includes disjoining semiconductor components of the row of semiconductor components while positioned on the support surfaces, at the first pitch, at locations coincident with gaps defined between the support surfaces. Additionally, the method includes, after disjoining the semiconductor components of the row of semiconductor components, translationally moving the support surfaces relative to each other in the second direction to increase a pitch between adjacent support surfaces from the first pitch to a second pitch.

In some implementations, the method further includes releasably locking the support surfaces in place at the second pitch by positioning a spacer in each of the gaps defined between the support surfaces. Positioning the spacer in each of the gaps defined between the support surfaces may include separately positioning groupings of spacers in the gaps in sequence along the support surfaces in the second direction.

According to certain implementations, the method additionally includes releasably coupling a first tray, that includes receptacles having the second pitch between adjacent receptacles, with the support surfaces, at the second pitch, such that each receptacle is aligned with a respective one of the semiconductor components in a fourth direction perpendicular to the first and second directions. The method also includes, with the first tray releasably coupled with the support surfaces, washing the first tray, support surfaces, and semiconductor components to decouple the semiconductor components from the support surfaces. Furthermore, the method includes transferring each of the semiconductor components decoupled from the support surfaces to within respective receptacles of the first tray. The method may additionally include applying negative pressure to the semiconductor components within the receptacles of the first tray to retain the semiconductor components within the receptacles of the first tray. Also, the method may include, while applying the negative pressure to the semiconductor components within the receptacles of the first tray, decoupling the support surfaces from the first tray. Additionally, the method can include, after decoupling the support surfaces from the first tray, releasably coupling a second tray, that includes receptacles having the second pitch between adjacent receptacles, with the first tray such that each semiconductor component within the receptacles of the first tray is aligned with a respective one of the receptacles of the second tray in a fifth direction opposite the fourth direction. The method can also include transferring the semiconductor components from within the receptacles of the first tray to within respective receptacles of the second tray, applying negative pressure to the semiconductor components within the receptacles of the second tray to retain the semiconductor components within the receptacles of the second tray, and, while applying the negative pressure to the semiconductor components within the receptacles of the second tray, decoupling the first tray from the second tray.

The described features, structures, advantages, and/or characteristics of the subject matter of the present disclosure may be combined in any suitable manner in one or more embodiments and/or implementations. In the following description, numerous specific details are provided to impart a thorough understanding of embodiments of the subject matter of the present disclosure. One skilled in the relevant art will recognize that the subject matter of the present disclosure may be practiced without one or more of the specific features, details, components, materials, and/or methods of a particular embodiment or implementation. In other instances, additional features and advantages may be recognized in certain embodiments and/or implementations that may not be present in all embodiments or implementations. Further, in some instances, well-known structures, materials, or operations are not shown or described in detail to avoid obscuring aspects of the subject matter of the present disclosure. The features and advantages of the subject matter of the present disclosure will become more fully apparent from the following description and appended claims, or may be learned by the practice of the subject matter as set forth hereinafter.

### BRIEF DESCRIPTION OF THE DRAWINGS

In order that the advantages of the subject matter may be more readily understood, a more particular description of the subject matter briefly described above will be rendered by reference to specific embodiments that are illustrated in the appended drawings. Understanding that these drawings depict only typical embodiments of the subject matter and are not therefore to be considered to be limiting of its scope, the subject matter will be described and explained with additional specificity and detail through the use of the drawings, in which:

FIG. 1 is a perspective view of a fixture for processing semiconductor components, according to one or more embodiments of the present disclosure;

FIG. 2 is a top plan view of the fixture of FIG. 1, according to one or more embodiments of the present disclosure;

FIG. 3 is an enlarged perspective view of an expandable portion of the fixture of FIG. 1, according to one or more embodiments of the present disclosure;

FIG. 4 is a top plan view of the fixture of FIG. 1, shown with portions of a frame of the fixture removed for clarity in showing locking elements of the fixture, according to one or more embodiments of the present disclosure;

FIG. 5 is a perspective view of the fixture of FIG. 1, shown with an expandable portion of the fixture in an expanded state, according to one or more embodiments of the present disclosure;

FIG. 6 is a cross-sectional perspective view of the fixture of FIG. 1, shown with an expandable portion of the fixture in a retracted state, according to one or more embodiments of the present disclosure;

FIG. 7 is a cross-sectional perspective view of the fixture of FIG. 1, shown with an expandable portion of the fixture in an expanded state, according to one or more embodiments of the present disclosure;

FIG. 8 is a perspective view of a fixture for processing semiconductor components, shown with an expandable portion of the fixture in a retracted state, according to one or more embodiments of the present disclosure;

FIG. 9 is a perspective view of the fixture of FIG. 8, shown with the expandable portion of the fixture in an expanded state, according to one or more embodiments of the present disclosure;

FIG. 10 is a perspective view of a tray of a system for processing semiconductor components, according to one or more embodiments of the present disclosure;

FIGS. 11-16 are schematic side elevation views of a system for processing semiconductor components in respective stages of processing the semiconductor components; and

FIG. 17 is a block diagram of a method of processing semiconductor components, according to one or more embodiments of the present disclosure.

### DETAILED DESCRIPTION

Reference throughout this specification to “one embodiment,” “an embodiment,” or similar language means that a particular feature, structure, or characteristic described in connection with the embodiment is included in at least one embodiment of the present disclosure. Appearances of the phrases “in one embodiment,” “in an embodiment,” and similar language throughout this specification may, but do not necessarily, all refer to the same embodiment. Similarly, the use of the term “implementation” means an implementation having a particular feature, structure, or characteristic described in connection with one or more embodiments of the present disclosure, however, absent an express correlation to indicate otherwise, an implementation may be associated with one or more embodiments.

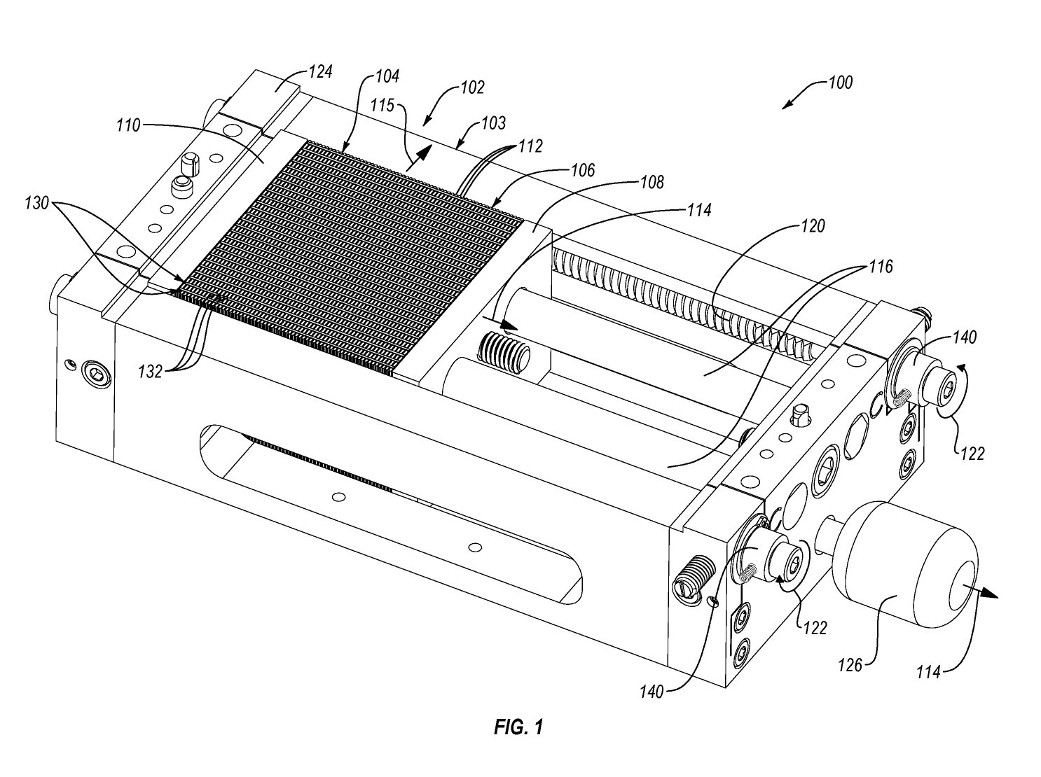

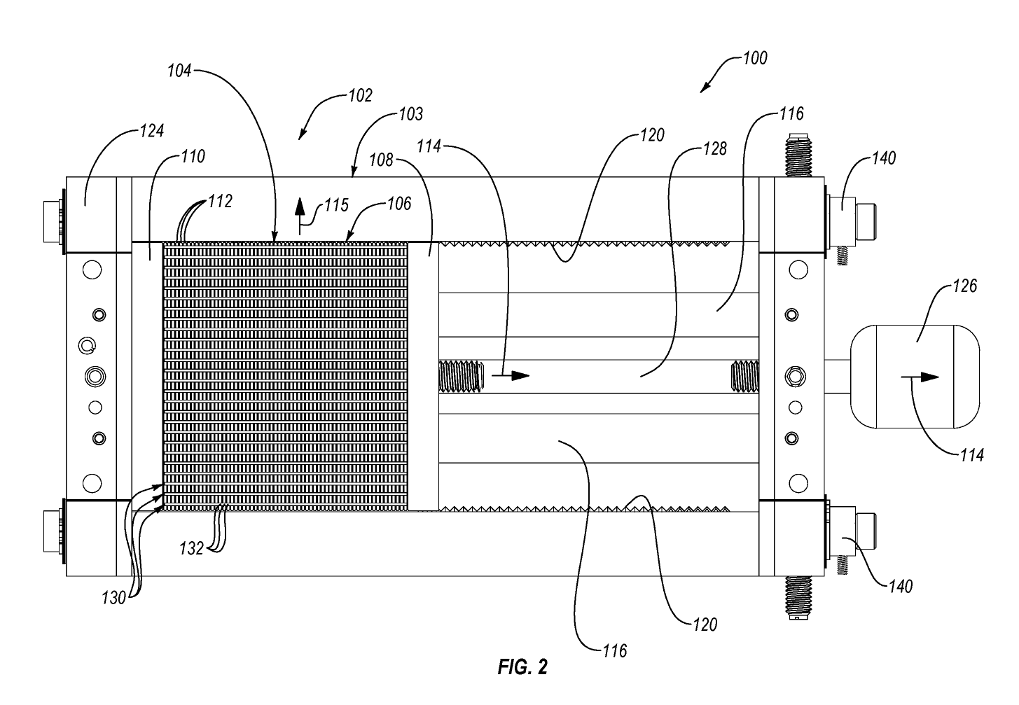

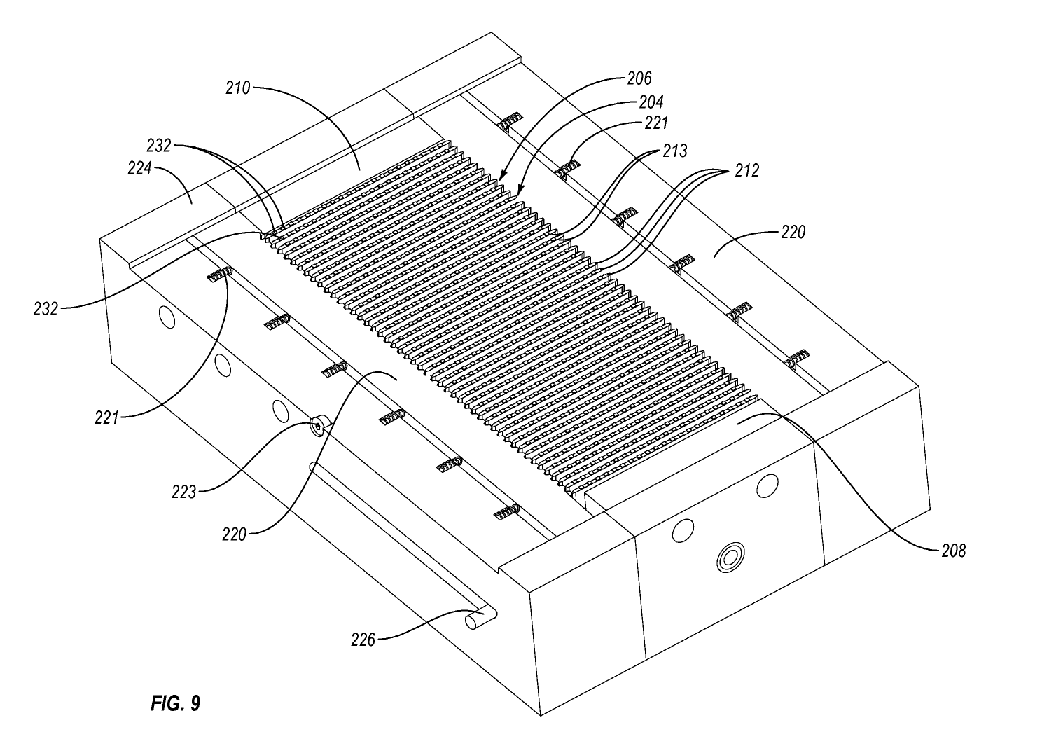

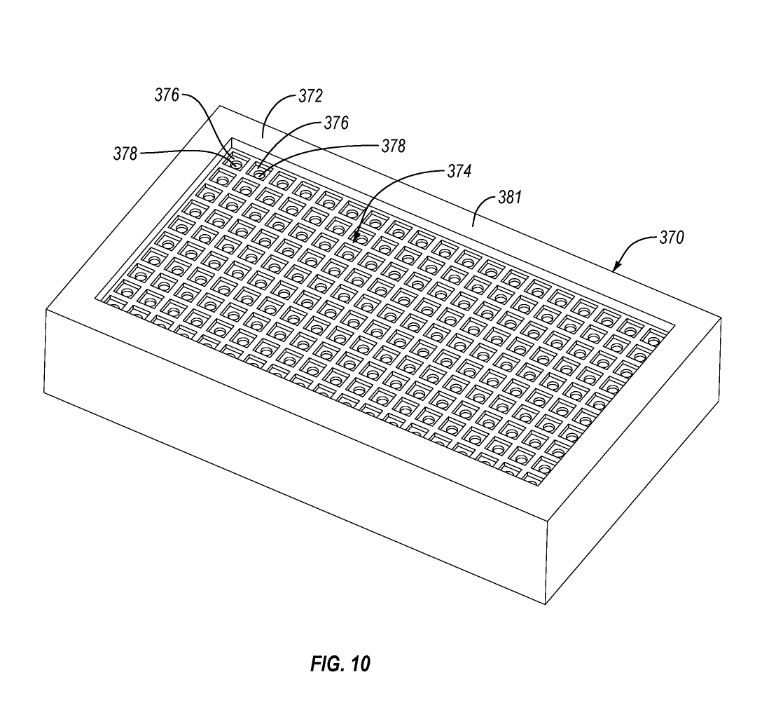

Referring to FIGS. 1-3, according to one embodiment, a system 100, for processing semiconductor components, includes a fixture 102. The fixture 102 includes a frame 103 that supports an expansion mechanism 104 of the fixture 102. Generally, the frame 103 is configured to support the expansion mechanism 104 as the expansion mechanism 104 translationally moves, relative to the frame 103, between a retracted state and an expanded state. The frame 103 includes an engagement surface 124 that is configured to engage an engagement surface of a tray (e.g., engagement surface 381 of tray 370 of FIG. 10) of the system 100. The engagement surface 124 of the frame 103 and the engagement surface of the tray complement each other. Accordingly, the frame 103 can have any of various configurations resulting in an engagement surface 124 that complements and is engageable with an engagement surface of a tray of the system 100. In the illustrated embodiment, the frame 103 includes two sidewalls, parallel to each other, coupled with two end walls, parallel to each other, to form a generally rectangular shape. However, in other embodiments, the frame 103 may have any number of sidewalls and/or end walls to form any of various other shapes, such as square, circular, triangular, and the like.

The frame 103 defines a cavity in which the expansion mechanism 104 is located. The cavity of the frame 103 has at least one open side contiguous with the engagement surface 124. Accordingly, the expansion mechanism 104 is accessible via the open end of the frame 103. The cavity of the frame 103 has an additional side, opposite the open side, which can be open or closed.

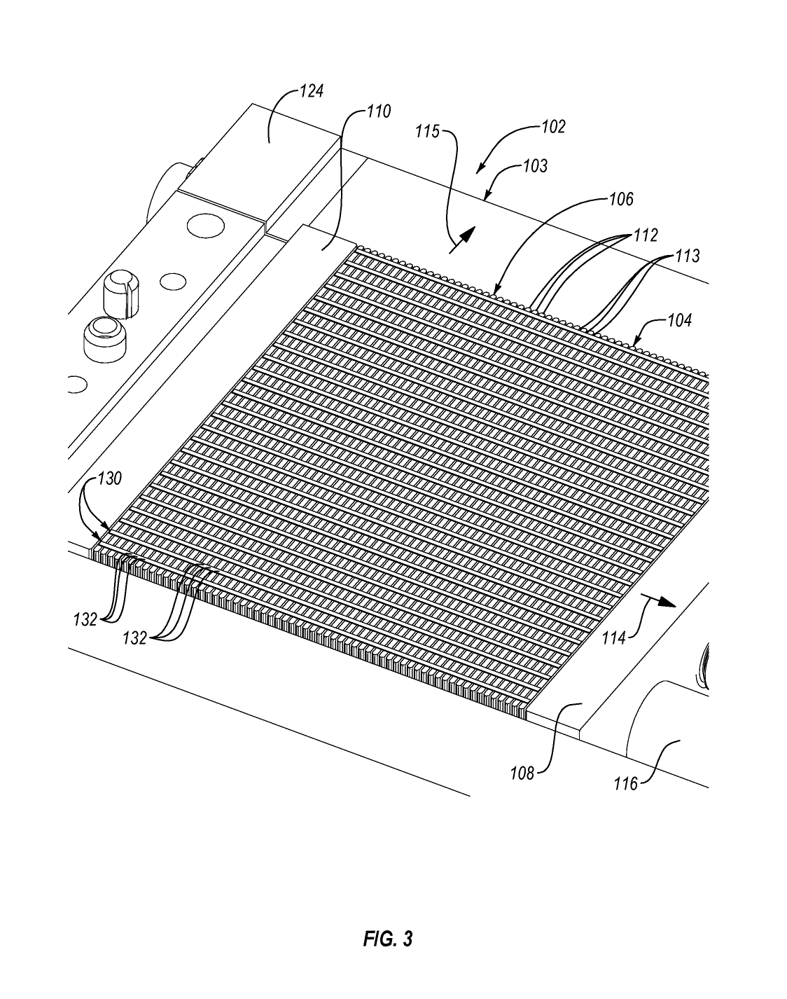

The expansion mechanism 104 includes an expandable portion 106, and a first end plate 108 and a second end plate 110. The expandable portion 106 is fixed to and interposed between the first end plate 108 and the second end plate 110. The first end plate 108 is movable relative to the frame 103, and the second end plate 110 is non-movable relative to the frame 103. Furthermore, the expandable portion 106 includes a plurality of support surfaces 112. Each of the support surfaces 112 is rigid and elongate. For example, each of the support surfaces 112 can be made from a metal, such as stainless steel, and can have a length greater than a width. The support surfaces 112 are arranged parallel to and spaced apart from each other between the first end plate 108 and the second end plate 110. Moreover, when the expansion mechanism 104 is supported by the frame 103, the support surfaces 112 extend lengthwise parallel to a first direction 115 and are spaced-apart from each other in a direction parallel to a second direction 114, which is perpendicular to the first direction 115. A gap 113 (shown in FIG. 3) is defined between respective adjacent support surfaces 112 of the expandable portion 106. Each gap 113 defines a minimum distance between adjacent support surfaces 112. The gaps 113 extend along the entire lengths of the support surfaces 112, in some implementations, such that no portion of a support surface 112 contacts an adjacent support surface 112.

The gaps 113 correlate with a pitch of the support surfaces 112. More specifically, the pitch of the support surfaces 112 is based on the minimum distance between adjacent support surfaces 112. As defined herein, a pitch of objects is the minimum distance between one point on an object and the corresponding point on an adjacent object. Accordingly, the pitch of the support surfaces 112 is the minimum distance between one point on a support surface 112 and the corresponding point on an adjacent support surface 112. Generally, the higher the minimum distance between adjacent support surfaces 112, the higher the pitch of the support surfaces 112, and the lower the minimum distance between adjacent support surfaces 112, the lower the pitch of the support surfaces 112. Accordingly, expanding the expandable portion 106, from a retracted state to an expanded state to increase the gaps 113, also increases the pitch of the support surfaces 112.

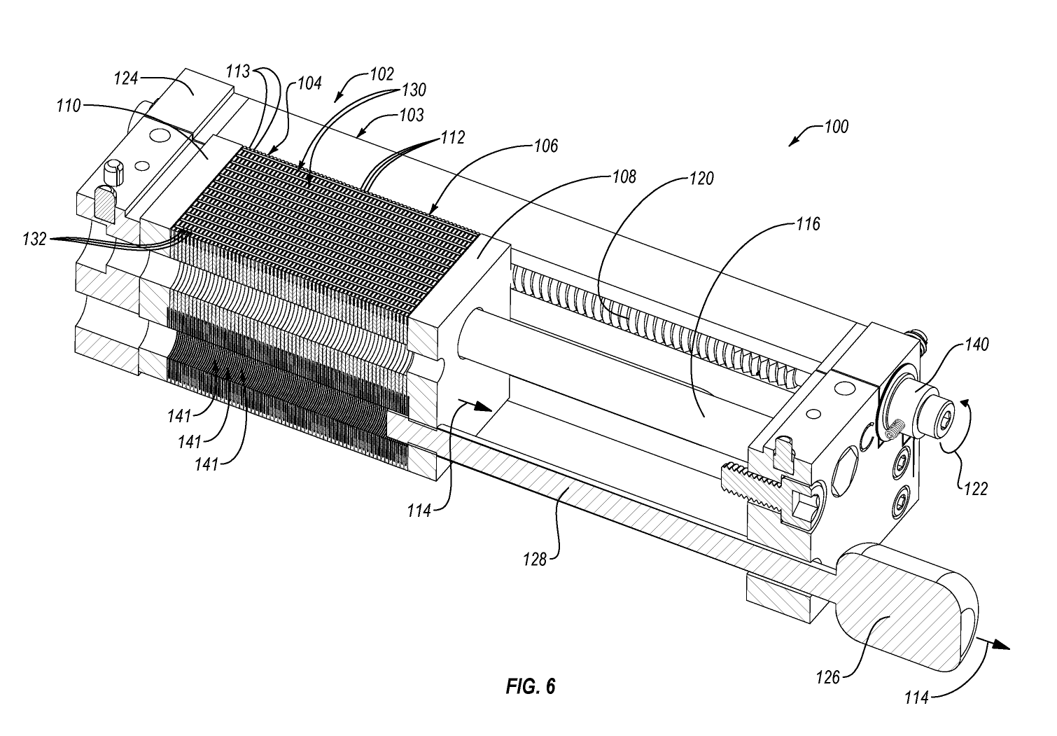

The expandable portion 106 of the expansion mechanism 104 also includes a plurality of flexible couplings 141 each positioned between and fixed to respective adjacent support surfaces 112. Each of the flexible couplings 141 couples together respective adjacent support surfaces 112. In this manner, the support surfaces 112 of the expandable portion 106 are flexibly linked together by the flexible couplings 141. Referring to FIGS. 6 and 7, according to one example, each flexible coupling 141 includes two thin-walled webs 143 each coupled to a respective one of adjacent support surfaces 112, along first sides of the webs 143, and coupled to each other, along second sides of the webs 143, opposite the first sides of the webs 143. The webs 143 of each flexible coupling 141 are configured to promote flexibility at least at the junction between the webs 143 and a respective one of the support surfaces 112 of adjacent support surfaces 112 and at the junction between the webs 143. Accordingly, in this example, the flexible couplings 141 are configured to cooperatively flex in an accordion-like, bellowed, or concertinaed manner to allow the expansion mechanism 104 to translationally move, relative to the frame 103, between the retracted state and the expanded state. More specifically, the webs 143 of each flexible coupling 141 flex away from each other as the expansion mechanism 104 expands, relative to the frame 103, from the retracted state (e.g., FIG. 6) to the expanded state (e.g., FIG. 7). In contrast, the webs 143 of each flexible coupling 141 flex toward each other as the expansion mechanism 104 retracts, relative to the frame 103, from the expanded state to the retracted state. In some implementations, the flexible couplings 141 are made from the same material as the supports surfaces. Also, the flexible couplings 141 can be co-formed with the support surfaces 112, such as via a machining process.

The flexible couplings 141 promote sequential relative movement of the support surfaces 112. Due to the flexible interconnectivity between support surfaces 112 provided by the flexible couplings 141, as one support surface 112 is translationally moved in a given direction, such as parallel to the second direction 114, to expand the expansion mechanism 104, the adjacent support surface 112 correspondingly translationally moves. Accordingly, by moving one support surface 112 in the given direction, all support surfaces 112 move in the given direction in a sequential manner by virtue of the flexible interconnectivity provided by the support surfaces 112.

Although in the example of FIGS. 6 and 7, the flexible couplings 141 each includes two flexible webs 143, in other examples, each flexible coupling 141 includes other configurations that facilitate relative movement of the support surfaces 112 between the expanded and retracted states.

In some implementations, one or two webs 143 may be positioned between and fixed to a support surface 112, at a first end of the expandable portion, and the first end plate 108, to flexibly couple together the support surface 112, at the first end of the expandable portion 106, and the first end plate 108. Similarly, one or two webs 143 may be positioned between and fixed to a support surface 112, at a second end of the expandable portion 106, and the second end plate 110, to flexibly couple together the support surface 112, at the second end of the expandable portion 106, and the second end plate 110. In such implementations, expansion and retraction of the expandable portion 106 can be facilitated by moving the first end plate 108 relative to the second end plate 110 in opposite directions. For example, moving the first end plate 108, relative to the second end plate 110, in the second direction 114, expands the expandable portion 106 and moving the first end plate 108, relative to the second end plate 110, in a direction opposite the second direction 114 retracts the expandable portion 106.

Returning to FIGS. 1-3, the fixture 102 additionally includes a linear actuator 126 that is configured to promote the expansion and retraction of the expandable portion 106. The linear actuator 126 is fixed to an end of the expandable portion 106 in a manner that promotes co-movability of the expandable portion 106 and the linear actuator 126. In other words, movement of the linear actuator 126 causes movement of the expandable portion 106. More specifically, translational movement of the linear actuator 126 in the second direction 114 causes the linear actuator 126 to expand in the second direction 114, and translational movement of the linear actuator 126 in a third direction, opposite the second direction 114, causes the linear actuator 126 to retract in the third direction. In one implementation, the linear actuator 126 is non-movably fixed to the first end plate 108 of the expansion mechanism 104 to directly translationally move the first end plate 108, and translationally move the support surfaces 112 relative to each other, as the linear actuator 126 moves. In one embodiment, the linear actuator 126 is an automatically-operated linear actuator, such as a pneumatic, hydraulic, piezoelectric, and/or electro-mechanical linear actuator. Such automatically-operated linear actuators can be selectively controlled via a programmable computer controller. Alternatively, in some embodiments, such as shown in FIGS. 1-7, the linear actuator 126 is a manually-operated linear actuator.

The linear actuator 126 may be at least partially supported by the frame 103. For example, for a manually-operated linear actuator, the frame 103 may include an aperture through which a portion of the linear actuator 126 extends and on which the linear actuator 126 is supported as the linear actuator 126 is translationally moved. Furthermore, to help facilitate gripping of a manually-operated linear actuator, the linear actuator 126 may include a knob, or other gripping feature, that a user may grip when translationally moving the linear actuator 126.

The fixture 102 also includes one or more linear rails 116 fixed to the frame 103 and non-movable relative to the frame 103. The linear rails 116 are parallel to each other and to the second direction 114. The expansion mechanism 104 is supported on and movable translationally along the linear rails 116. In this manner, the linear rails 116 help to promote translational movement of the expandable portion 106 of the expansion mechanism 104 in the second direction 114 and third direction, opposite the second direction 114, without binding of the expandable portion 106. The expansion mechanism 104 includes two channels that extend through the first end plate 108 and at least a portion of the expandable portion 106. Each of the linear rails 116 extends through a respective of the channels of the expansion mechanism 104 to retain the first end plate 108 and expandable portion 106 on the linear rails 116.

Additionally, the fixture 102 includes at least one locking element 120 that is configured to lock the expandable portion 106 of the expansion mechanism 104 in the expanded state. In some embodiments, the fixture includes two locking elements 120 positioned on opposite sides of the expandable portion 106. The locking elements 120 are movably fixed to the frame 103 of the fixture 102. Each locking element 120 includes spacers 144 that are spaced apart at a third pitch corresponding with a desired pitch between the support surfaces 112 in the expanded state. The spacers 144 are sized to fit within the gaps 113 between the support surfaces 112, with each spacer 144 fitting within a respective one of the gaps 113. Moreover, when positioned within the gaps 113, the spacers 144 are sized to, at least indirectly, engage the support surfaces 112 to maintain the desired pitch between the support surfaces 112. The spacers 144 can have any of various shapes. In some implementations, each of the spacers 144 is tooth-shaped or wedge-shaped to promote centering of the spacers 144 within respective gaps 113 as the spacers 144 are inserted into the respective gaps 113. Insertion of the spacers 144 of the locking elements 120 into the gaps 113 is accomplished by actuation of the locking elements 120. The locking elements 120 can be actuated automatically or manually.

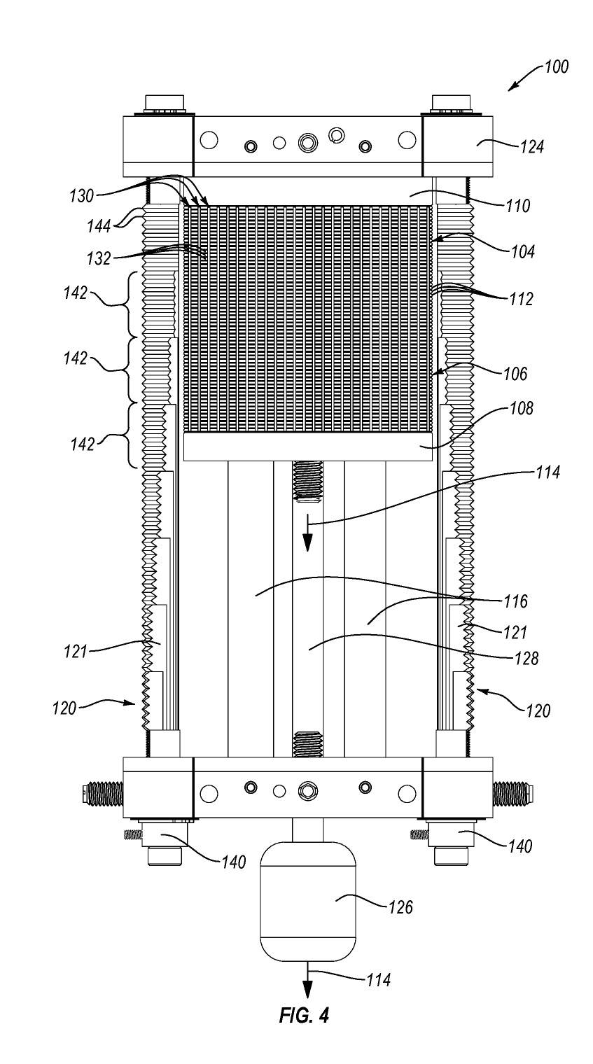

In the embodiments of FIGS. 1-7, the locking elements 120 are actuated manually or automatically by rotating the locking elements 120. Each locking element 120 of FIGS. 1-7 includes a shaft 121 with the spacers 144 being positioned in a side-by-side arrangement along a central axis of the shaft 121. For each locking element 120, the spacers 144 extend circumferentially around only a portion of the circumference of the shaft 121. Accordingly, a portion of the shaft 121 is not covered by the spacers 144. Moreover, in certain implementations, depending on the location of the spacers 144 along the axis of the shaft 121, some spacers 144 may extend circumferentially around a greater or lesser portion of the circumference of the shaft 121 than other spacers 144. In other words, the circumferential length of the spacers 144 may be different based on the location of the spacers 144 on the shaft 121. For example, referring to FIG. 4, the spacers 144 may be separated into groupings of spacers 142 each including one or more spacers 144.

The spacers 144 of the same grouping of spacers 142 have the same circumferential length and are arranged on the same circumferential portion of the shaft 121 of a locking element 120. Moreover, the circumferential length of the spacers 144 of one grouping of spacers 142 is different than the circumferential length of the spacers 144 of an adjacent grouping of spacers 142. In one implementation, as shown, the circumferential length of the spacers 144 of one grouping of spacers 142 is more than the circumferential length of the spacers 144 of an adjacent grouping of spacers 142 in the second direction 114. In other words, in the second direction 114, the circumferential length of the spacers 144 from grouping of spacers 142 to grouping of spacers 142 incrementally decreases. Furthermore, despite the differing circumferential lengths of the spacers 144, the circumferential location of the spacers 144 on the shaft 121 for each grouping of spacers 142 is aligned along an axis of the shaft 121. For example, in one implementation, as shown, the groupings of spacers 142 are arranged in a step-wise manner along the shaft 121.

In operation, after the expandable portion 106 is expanded into the expanded state, the locking elements 120 of FIGS. 1-7 can be rotated in the rotational direction 122. In some implementations, a handle 140 is co-rotatable coupled with each of the locking elements 120 to facilitate manual rotation of the locking elements 120. In alternative implementations, the locking elements 120 can be automatically rotated via any of various electronically controllable devices, such as motors, actuators, and the like. Rotation of the locking elements 120 causes the spacers 142 to be inserted in the gaps 113 between the spacers 144 to uniformly space the support surfaces 112 apart from each other at the desired pitch and lock the expandable portion 106 of the expansion mechanism 104 in the expanded state. The configuration of the locking elements 120 of FIGS. 1-7 helps to facilitate incremental or progressive insertion of the spacers 144 into the gaps 113 one grouping of spacers 142 at a time. For example, as the locking elements 120 are rotated, the spacers 144 of one grouping of spacers 142 are first inserted into a corresponding set of gaps 113. Further rotation of the locking elements 120 causes the spacers 144 of an adjacent grouping of spacers 142, in the second direction 114, to subsequently be inserted into another corresponding set of gaps 113. Additional rotation of the locking elements 120 then results in the spacers 144 of the remaining grouping of spacers 142 to be progressively inserted into corresponding sets of gaps 113. In this manner, the spacing between the support surfaces 112 is uniformly spaced and locked a few of the support surfaces 112 at a time, which helps to reduce misalignment or binding between the gaps 113 and the spacers 142 during the insertion process.

Generally, with the expandable portion 106 of the expansion mechanism 104 in the retracted state (see, e.g., FIGS. 1-4 and 6), the support surfaces 112 are configured to be coupled to (e.g., receive and support thereon) at least one row 130 made of semiconductor components 132 adjoined together. According to some embodiments, as shown, the support surfaces 112 receive thereon and support a plurality of rows 130 of semiconductor components 132. As defined herein, the semiconductor components 132 of a row 130 are considered adjoined semiconductor components because the semiconductor components 132 are joined together. In some implementations, the semiconductor components 132 of the row 130 are arranged one at a time in an end-to-end manner along a length of the row 130. In this manner, the row 130 of semiconductor components 132 extends in a direction along the length of the row 130. Each row 130 is oriented on the support surfaces 112 to extend parallel to the second direction 114 such that each row 130 is supported by multiple support surfaces 112. More specifically, in the retracted state, the support surfaces 112 are spaced apart from each other such that each support surface 112 supports a respective one of the semiconductor components 132 of a row 130. Where the support surfaces 112 support multiple rows 130, the rows 130 can be fixed onto the support surfaces 112 parallel to each other and a desired distance apart from each other, in the first direction 115. The rows 130 of semiconductor components 132 are non-movably fixedly supported on the support surfaces 112 via a bonding agent applied between the rows 130 and the support surfaces 112.

In certain implementations, each row 130 of semiconductor components 132 is separated from a plurality of semiconductor components 132 co-formed on a wafer. For example, the wafer may include an array of semiconductor components 132 across the surface of the wafer. The semiconductor components 132 may be categorized into one of several quads of semiconductor components 132 with each quad having a given number of rows of semiconductor components with a given number of semiconductor components per row. Generally, to increase the number of semiconductor components 132 manufactured per batch, and thus reduce costs and labor, the areal density of semiconductor components on the wafer desirably is maximized (e.g., the pitch between adjacent semiconductor components of a given row is minimized). After the semiconductor components 132 are formed on the wafer, the rows 130 of semiconductor components 132 are formed by physically separating semiconductor components 132, arranged in rows on the wafer, from each other. The rows 130 are physically separated by a cutting process, such as with a knife, cutting wheel, laser, etc., in some implementations, or by an additional or alternative separation process in other implementations.

The semiconductor components 132 can be any of various components used for any of various applications. In one embodiment, each semiconductor component 132 is a slider for a hard disk drive or other magnetic recording medium device. The slider includes an integrated circuit for providing magnetic-bit reading capabilities and magnetic-bit writing capabilities. The semiconductor components 132 can be made from any of various semiconductor materials, such as silicone. In yet other embodiments, the semiconductor components 132 can be made from materials other than semiconductor materials.

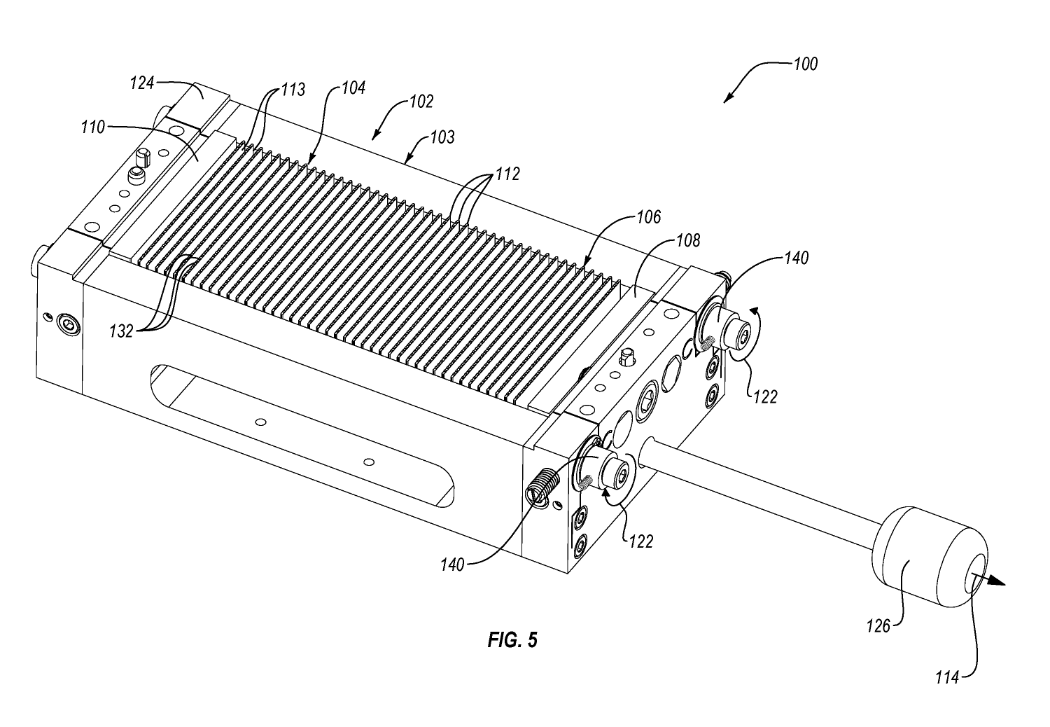

Generally, as will be described in more detail below, after the rows 130 of semiconductor components 132 are fixed on the support surfaces 112 in the retracted state, the semiconductor components 132 of each row 130 are physically separated or disjoined from each other. When the semiconductor components 132 of each row 130 are physically separated from each other, the support surfaces 112 can be moved relative to each other in the second direction 114 into the expanded state (see, e.g., FIGS. 5 and 7) to increase the pitch between the support surfaces 112, and thus the pitch between the physically separated semiconductor components 132, by actuating the linear actuator in the second direction 114. After expanding the expandable portion 106 into the expanded state to increase the pitch between the support surfaces 112 and the semiconductor components 132, the support surfaces 112 can be locked into place by actuating the locking elements 120.

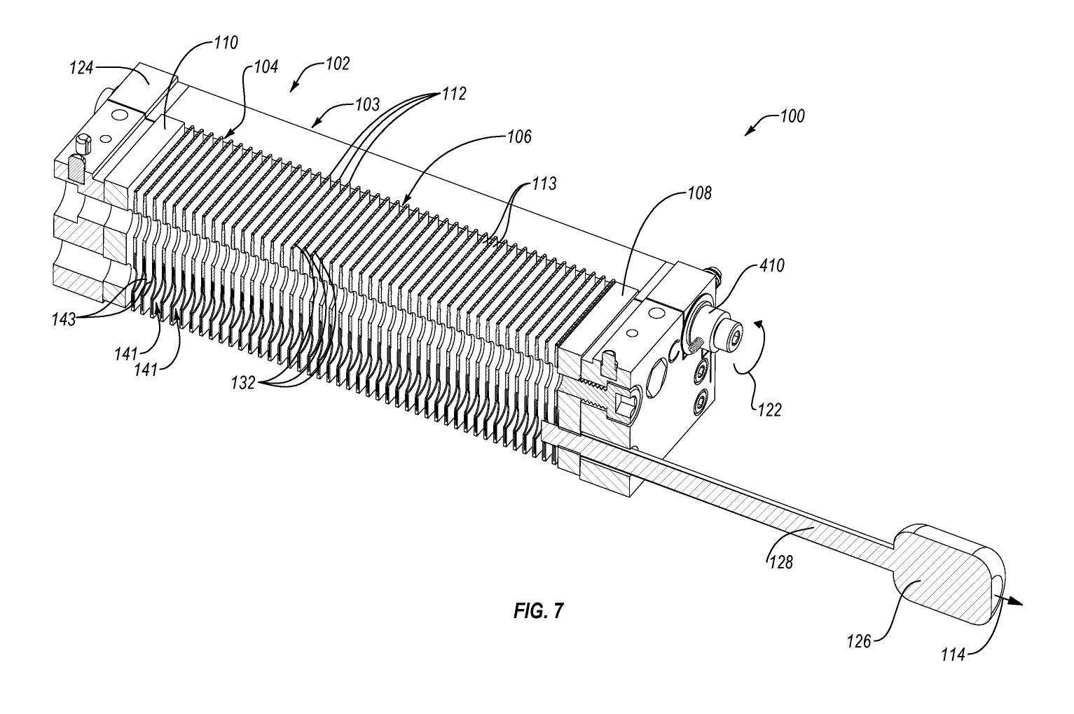

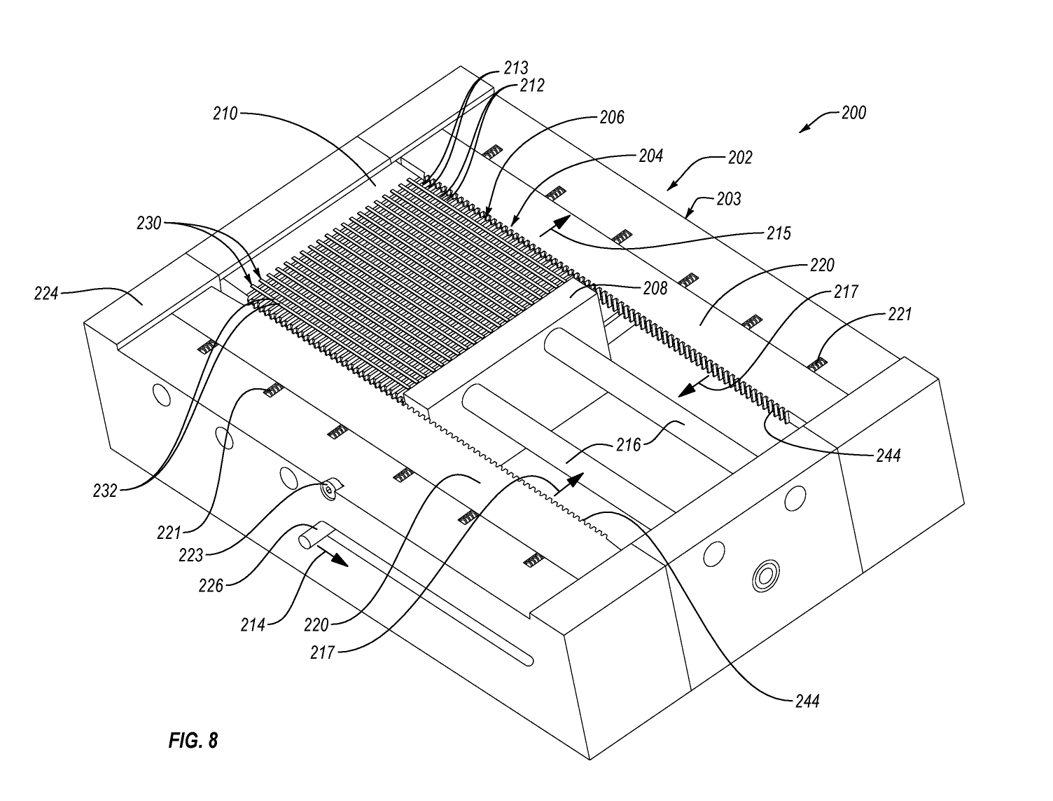

Referring to FIGS. 8 and 9, according to another embodiment of a system 200 and fixture 202, similar to the system 100 and fixture 102 of FIGS. 1-7, with like numbers referring to like features, locking elements 220 are actuated manually by translationally moving the locking elements 220 to position spacers 244 within gaps 213 between support surfaces 212. Each of the locking elements 220 includes a bar with spacers 244 linearly-aligned along the bar and facing the expandable portion 206. The fixture 202 further includes biasing elements 221, such as compression springs, engaged with the locking elements 220 to bias the locking elements 220 into engagement with the expandable portion 206 (e.g., insertion of the spacers 244 into the gaps 213). Translational movement of the locking elements 220 can be facilitated by rotation of fasteners 223 each fixed to the frame 203 and threadably engaged with a respective one of the locking elements 220. Different than the locking elements 120 of the fixture 102, with the expandable portion 206 in the expanded state, the locking elements 220 of the fixture 202 are configured to insert all the spacers 244 into the gaps 213 at the same time. Also, in contrast to the linear actuator 126 of the fixture 102, the linear actuator 226 of the fixture 202 includes opposing sliders extending transversely relative to the second direction 214. The sliders of the linear actuator 226 extend from the sides of the frame 203, to provide opposing handles, and slide along slots formed in the frame 203, to manually expand and retract the expandable portion 206.

Referring to FIG. 10, the system 100 further includes a tray 370 for individually retaining disjoined semiconductor components separate from each other. The tray 370 includes a frame 372 and a component retainer portion 374 fixed to the frame 372. The frame 372 defines the engagement surface 381, which, as described above, is configured to engage the engagement surface 124 of the frame 103 of the fixture 102. The component retainer portion 374 includes a plurality of receptacles 376 each sized and shaped to receive and retain a respective one of the semiconductor components of the rows of semiconductor components after they have been disjoined from each other. To facilitate the receipt and retainment of disjoined semiconductor components, the receptacles 376 are spaced apart from each other, in a direction parallel to the second direction 114, at a fourth pitch equal to the desired pitch (e.g, second pitch P2 (see, e.g., FIG. 13)) of the support surfaces 112 in the expanded state. Moreover, the receptacles 376 can be spaced apart from each other, in a direction parallel to the first direction 115, at a pitch equal to the spacing between adjacent rows of semiconductor components when supported on the support surfaces 112. Accordingly, the tray 370 can be releasably coupled to the frame 103, via engagement between engagement surfaces 124, 381, over the support surfaces 112 and disjoined semiconductor components 132 in the expanded state such that each receptacle is aligned, in a direction perpendicular to the first direction 115 and the second direction 114, with a respective one of the semiconductor components 132. In some implementations, the pitch between the receptacles 376 in the first direction 115 and the pitch between the receptacles 376 in the second direction 114 is the same. The component retainer portion 374 of the tray 370 additionally includes apertures 378 each formed in a respective one of the receptacles 376.

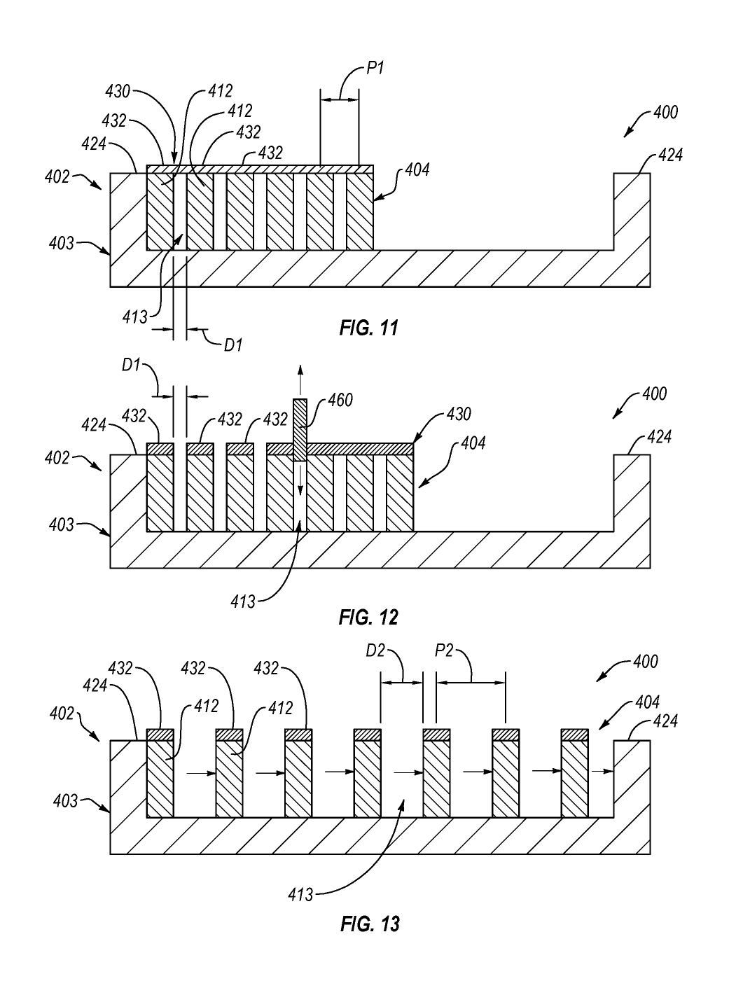

Referring to FIGS. 11-16, according to another embodiment, a system 400, for processing semiconductor components that similar to the system 100 and the system 200, with like numbers referring to like features, is shown schematically. The system 400 includes a fixture 402, with a frame 403, and an expansion mechanism 404, movably fixed to the frame 403. The frame 403 includes an engagement surface 424.

With reference to FIG. 11, the expansion mechanism 404 is in a retracted state. In the retracted state, the support surfaces are positioned relative to each other such that a minimum distance D1 is defined between adjacent support surfaces 412. The minimum distance D1 correlates with a first pitch P1 of the support surfaces 412 in the retracted state. At least one row 430 of semiconductor components 432, adjoined together and having a pitch equal to the first pitch P1, is coupled to the support surfaces 412. With the pitch of the semiconductor components 432 of the row 430 being equal to the first pitch P1 of the support surfaces 412, the row 430 of semiconductor components 432 can be positioned relative to the support surfaces 412 such that each one of the semiconductor components 432 is aligned with or supported by a respective one of the support surfaces 412. Although not shown, a layer of bonding agent may be positioned between the support surfaces 412 and the semiconductor components 432 to bond each semiconductor component 432 to a respective support surface 412.

Now referring to FIG. 12, the semiconductor components 432 of the row 430 (or of each row 430 if there are multiple rows 430) are disjoined or separated from each other while coupled to the support surfaces 412. In the implementation shown, a cutting device 460 is passed between adjacent semiconductor components 432 of the row 430 to effectively form a gap between the adjacent semiconductor components 432, thus disjoining the adjacent semiconductor components 432. The cutting device 460 can be any of various devices capable of cutting through semiconductor materials, such as rotary saws, reciprocating saws, lasers, razor blades, wire electrical discharge machining (EDM), and the like. As shown, the cutting device 460 may at least partially pass through the gaps 413 between the semiconductor components 432 to facilitate a complete disjoining of adjacent semiconductor components 432.

After the semiconductor components 432 of the row 430 are disjoined, as shown in FIG. 13, the support surfaces 412 are moved relative to each other in the direction indicated to increase the gap 413 between each of the adjacent support surfaces 412, and thus the gap between adjacent semiconductor components 432, from the first minimum distance D1, associated with the expansion mechanism 404 in the retracted state, to a second minimum distance D2, associated with the expansion mechanism 404 in the expanded state. Increasing the size of the gap 413 between adjacent support surfaces 412 results in an increase in the pitch of the support surfaces 412 from the first pitch P1, associated with the expansion mechanism 404 in the retracted state, to a second pitch P2, associated with the expansion mechanism in the expanded state. In some implementations, the second pitch P2 is at least two times greater than the first pitch P1.

With the expansion mechanism 404, having the disjoined semiconductor components 432 coupled thereto, in the expanded state, a first tray 470A of the system 400 can be releasably coupled to the fixture 402 via engagement between the engagement surface 424 of the frame 403 and an engagement surface 481A of the first tray 470A. The first tray 470A includes receptacles 476A, separate and distinct from each other, spaced apart from each other at a fourth pitch equal to the second pitch P2. Accordingly, with the first tray 470A coupled to the fixture 402, the semiconductor components 432 are at least partially positioned within a respective one of the receptacles 476A.

In some implementations, due the material and manufacturing limitations, the fourth pitch between the receptacles 476A of the first tray 470A is the smallest pitch possible. However, as presented above, the semiconductor components 432 can be and are desirably manufactured to have a first pitch P1 smaller than the fourth pitch. Accordingly, providing a fixture 402 that enables the increase of the pitch of the semiconductor components 432 from the first pitch P1 to the second pitch P2, which can be equal to the fourth pitch of the receptacles 476A, allows the semiconductor components 432 to be manufactured at a relatively smaller pitch, while ensuring compatibility with manufacturing process equipment having a relatively larger pitch.

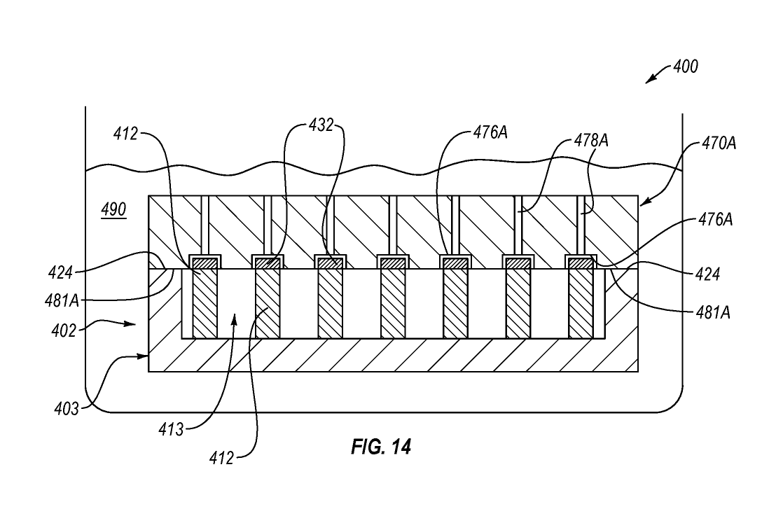

Also shown in FIG. 14, the fixture 402, with the first tray 470A releasably coupled thereto, can be placed in a chemical wash 490 or bath and washed to remove the bonding agent from between the semiconductor components 432 and the support surfaces 412. The chemical wash 490 can be any of various solvents that, when used in conjunction with any of various washing processes, such as an ultrasonic-frequency washing process, is configured to break down the bonding agent. Removal of the bonding agent effectively decouples the semiconductor components 432 from the support surfaces 412. In some implementations, before or after decoupling the semiconductor components 432 from the support surfaces 412, the fixture 402 and first tray 470A can be flipped 180-degrees, such that the first tray 470A is vertically below the fixture 402. Accordingly, in such implementations, when the semiconductor components 432 decouple from the support surfaces 412, the semiconductor components 432 can fall into respective receptacles 476A of the first tray 470A.

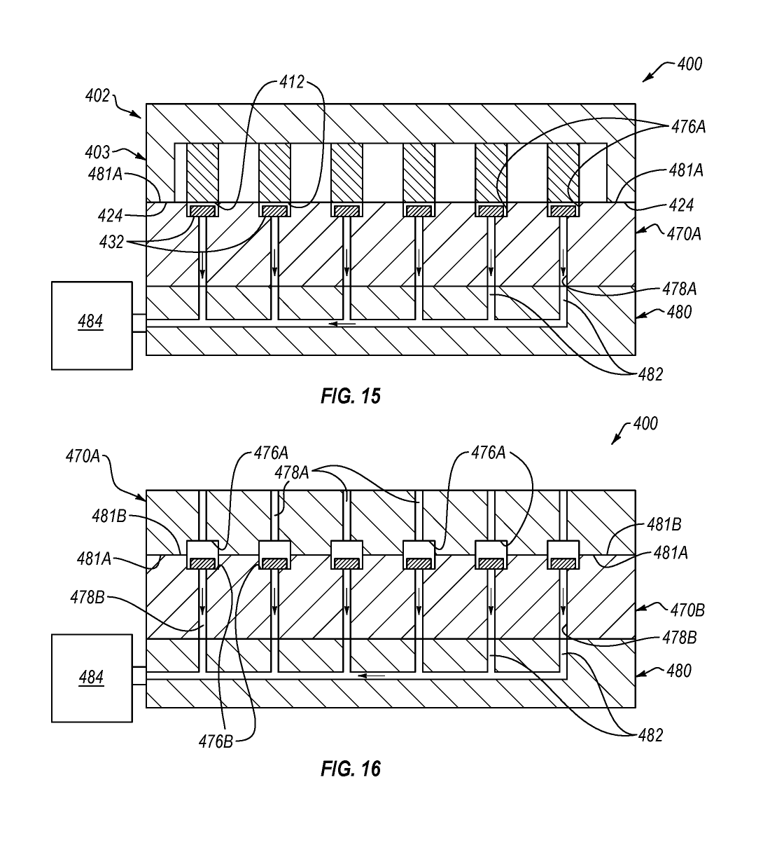

Referring to FIG. 15, with the first tray 470A releasably coupled to the fixture 402, a vacuum base 480 can be releasably coupled to the first tray 470A. The vacuum base 480 includes at least one fluid conduit 482 communicatively coupled with apertures 478A of the first tray 470A. In some implementations, the at least one fluid conduit 482 includes a plurality of intercoupled fluid conduits each communicatively coupled with a respective one of the apertures 478A. The system 400 further includes a vacuum 484 that is communicatively coupleable with the at least one fluid conduit 482 of the vacuum base 480. The vacuum 484 is selectively operable to draw air from the receptacles 476A of the first tray 470A via the apertures 478A of the first tray 470A and the at least one fluid conduit 482 of the vacuum base 480 when the vacuum 484 is communicatively coupled with the at least one fluid conduit 482 of the vacuum base 480 and the vacuum base 480 is releasably coupled to the first tray 470A. Generally, selective operation of the vacuum 484 applies a negative pressure to the semiconductor components 432 within the receptacles 476A, to retain the semiconductor components 432 within the receptacles 476A. Alternatively, in implementations where the fixture 402 is vertically below the first tray 470A after the bonding agent is removed, selective operation of the vacuum 484 applies a negative pressure to the semiconductor components 432 to draw the semiconductor components 432 from the support surfaces 412 into the receptacles 476A and then retain the semiconductor components 432 within the receptacles 476A.

While the vacuum 484 applies the negative pressure to the semiconductor components 432 within the receptacles 476A of the first tray 470A, the fixture 402, including the support surfaces 412, is decoupled from the first tray 470A. The application of negative pressure to the semiconductor components 432, while decoupling the fixture 402 from the first tray 470A, helps to ensure the semiconductor components 432 are retained within the receptacles 476A of the first tray 470A and do not remain on the fixture 402, such as due to any residual bonding agent left over after the washing process, as the fixture 402 is removed from the first tray 470A.

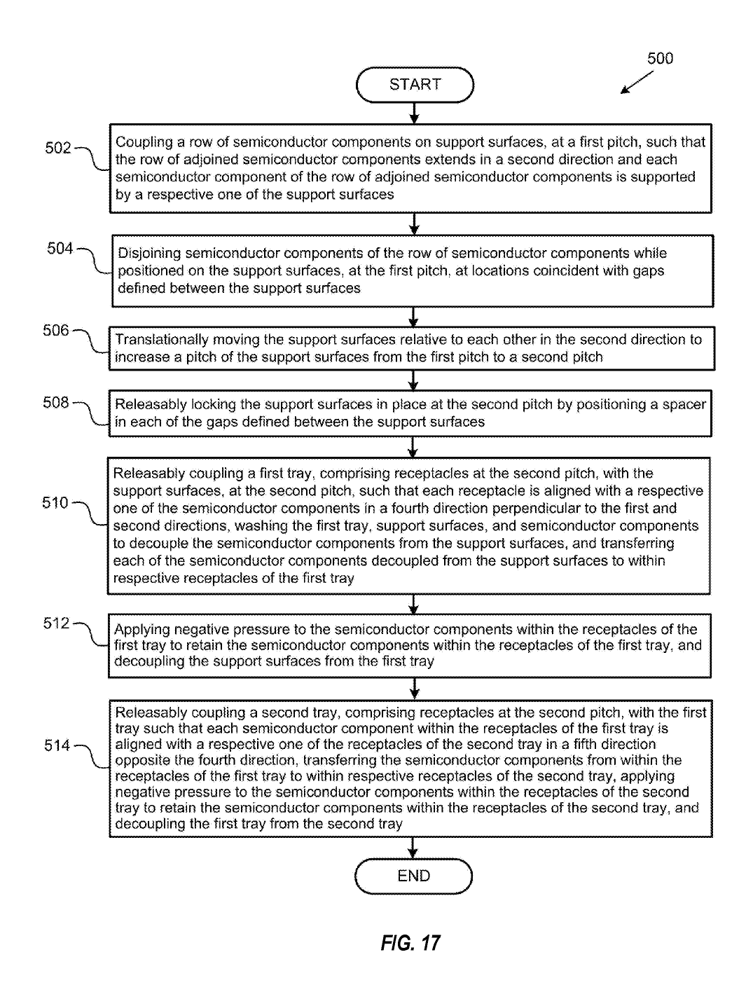

In some implementations, after the fixture 402 is removed from the first tray 470A, the upward-facing surfaces of the semiconductor components 432 within the receptacles 476A of the first tray 470A can be further processed, such as polished and/or etched. However, according to certain implementations, it may be desirable to further process the downward-facing surfaces of the semiconductor components 432 within the receptacles 476A of the first tray 470A. Therefore, referring to FIG. 16, after the fixture 402 is removed from the first tray 470A, a second tray 470B can be releasably coupled to the first tray 470A via engagement between the engagement surface 481A of the first tray 470A and an engagement surface 481B of the second tray 470B. Like the first tray 470A, the second tray 470B includes receptacles 476B, separate and distinct from each other, spaced apart from each other at a fifth pitch equal to the second pitch P2. Accordingly, with the second tray 470B coupled to the first tray 470A, the semiconductor components 432 within the receptacles 476A of the first tray 470A are aligned with the receptacles 476B of the second tray 470B. By flipping the first tray 470A and the second tray 470B 180-degrees, the semiconductor components 432 are transferred from within the receptacles 476A of the first tray 470A to within the receptacles 476B of the second tray 470B. Moreover, when transferred to the receptacles 476B of the second tray 470B, the previously downward-facing surfaces of the semiconductor components 432 are now upward-facing and thus accessible for further processing, such as polishing and/or etching. In implementations where the semiconductor components 432 are sliders, the upward-facing surface that receives further processing is an air bearing surface of the sliders.

Still referring to FIG. 16, with the second tray 470B releasably coupled to the first tray 470A and the semiconductor components 432 within the receptacles 476B of the second tray 470B, a vacuum base 480 can be releasably coupled to the second tray 470B. The vacuum base 480 can be the same vacuum base 480 that was releasably coupled to the first tray 470A in some implementations, or another vacuum base 480 in other implementations. According to the latter implementations, one vacuum base 480 can remain releasably coupled with the first tray 470A while the other vacuum base 480 is releasably coupled with the second tray 470B. As shown in FIG. 16, a vacuum 484 is selectively operable to draw air from the receptacles 476B of the second tray 470B via the apertures 478B of the second tray 470B and the at least one fluid conduit 482 of the vacuum base 480 when the vacuum 484 is communicatively coupled with the at least one fluid conduit 482 of the vacuum base 480 and the vacuum base 480 is releasably coupled to the second tray 470B. Generally, selective operation of the vacuum 484 applies a negative pressure to the semiconductor components 432 within the receptacles 476B of the second tray 470B, to retain the semiconductor components 432 within the receptacles 476B. While the vacuum 484 applies the negative pressure to the semiconductor components 432 within the receptacles 476B of the second tray 470B, the first tray 470A is decoupled from the second tray 470B. The application of negative pressure to the semiconductor components 432, while decoupling the first tray 470A from the second tray 470B, helps to ensure the semiconductor components 432 are retained within the receptacles 476B of the second tray 470B and do not remain within the receptacles 476A of the first tray 470A as the first tray 470A is removed.

Referring to FIG. 17, according to one embodiment, a method 500 of processing semiconductor components includes (block 502) coupling a row of semiconductor components on support surfaces, at a first pitch, such that the row of adjoined semiconductor components extends in a second direction and each semiconductor component of the row of adjoined semiconductor components is supported by a respective one of the support surfaces. The method 500 further includes (block 504) disjoining semiconductor components of the row of semiconductor components while positioned on the support surfaces, at the first pitch, at locations coincident with gaps defined between the support surfaces. Additionally, the method includes (block 506) translationally moving the support surfaces relative to each other in the second direction to increase a pitch of the support surfaces from the first pitch to a second pitch.

In some implementations, the method 500 further includes (block 508) releasably locking the support surfaces in place at the second pitch by positioning a spacer in each of the gaps defined between the support surfaces. Positioning the spacer in each of the gaps defined between the support surfaces may include separately positioning groupings of spacers in the gaps in sequence along the support surfaces in the second direction. Also, the method 500 may include (block 510) releasably coupling a first tray, comprising receptacles at the second pitch, with the support surfaces, at the second pitch, such that each receptacle is aligned with a respective one of the semiconductor components in a fourth direction perpendicular to the first and second directions, washing the first tray, support surfaces, and semiconductor components to decouple the semiconductor components from the support surfaces, and transferring each of the semiconductor components decoupled from the support surfaces to within respective receptacles of the first tray. The method 500 can also include (block 512) applying negative pressure to the semiconductor components within the receptacles of the first tray to retain the semiconductor components within the receptacles of the first tray and decoupling the support surfaces from the first tray. Furthermore, the method 500 may include (block 514) releasably coupling a second tray, that includes receptacles at the second pitch, with the first tray such that each semiconductor component within the receptacles of the first tray is aligned with a respective one of the receptacles of the second tray in a fifth direction opposite the fourth direction, transferring the semiconductor components from within the receptacles of the first tray to within respective receptacles of the second tray, applying negative pressure to the semiconductor components within the receptacles of the second tray to retain the semiconductor components within the receptacles of the second tray, and decoupling the first tray from the second tray.

In the above description, certain terms may be used such as “up,” “down,” “upwards,” “downwards,” “upper,” “lower,” “horizontal,” “vertical,” “left,” “right,” “over,” “under” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object. Further, the terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise. Further, the term “plurality” can be defined as “at least two.”

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example, without limitation, two of item A, one of item B, and ten of item C; four of item B and seven of item C; or some other suitable combination.

Unless otherwise indicated, the terms “first,” “second,” etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to” and/or as being “operative to” perform that function.

The present subject matter may be embodied in other specific forms without departing from its spirit or essential characteristics. The described embodiments are to be considered in all respects only as illustrative and not restrictive. All changes which come within the meaning and range of equivalency of the claims are to be embraced within their scope.

What is claimed is:

1. An apparatus for processing semiconductor components, the apparatus comprising:
support surfaces, parallel to a first direction and spaced apart from each other in a second direction, perpendicular to the first direction, wherein the support surfaces are translationally movable relative to each other in the second direction to increase a pitch between adjacent support surfaces from a first pitch to a second pitch; and
flexible couplings, each between and fixed to respective adjacent ones of the support surfaces, wherein the flexible couplings flex as the support surfaces translationally move relative to each other in the second direction.

2. The apparatus according to claim 1, further comprising a linear actuator fixed to one of the support surfaces, wherein the linear actuator is selectively operable to translationally move the support surfaces relative to each other in the second direction.

3. The apparatus according to claim 1, wherein adjacent support surfaces are co-movable in the second direction via the flexible coupling between and fixed to the adjacent support surfaces.

4. The apparatus according to claim 3, wherein:
the support surfaces are translationally movable relative to each other in a third direction, opposite the second direction, to decrease the pitch from the second pitch to the first pitch;
adjacent support surfaces are co-movable in the third direction via the flexible coupling between and fixed to the adjacent support surfaces; and
the flexible couplings flex as the support surfaces translationally move relative to each other in the third direction.

5. The apparatus according to claim 4, wherein:
the flexible couplings expand as support surfaces translationally move relative to each other in the second direction; and
the flexible couplings compress as support surfaces translationally move relative to each other in the third direction.

6. The apparatus according to claim 1, further comprising at least one locking element, comprising spacers having a third pitch between adjacent spacers, the third pitch being equal to the second pitch, wherein the at least one locking element is movable relative to the support surfaces to position respective spacers between adjacent support surfaces at the second pitch.

7. The apparatus according to claim 6, wherein the at least one locking element is translationally movable in the first direction relative to the support surfaces to position respective spacers between adjacent support surfaces at the second pitch.

8. The apparatus according to claim 6, wherein the at least one locking element is rotationally movable relative to the support surfaces to position respective spacers between adjacent support surfaces at the second pitch.

9. The apparatus according to claim 8, wherein:
the spacers of the at least one locking element are separated into groupings of spacers adjacent each other in the second direction along the at least one locking element;
each spacer of each grouping of spacers has a circumferential length different than each spacer of others of the groupings of spacers; and
a circumferential length of each spacer of any grouping of spacers is greater than a circumferential length of each spacer of any adjacent grouping of spacers in the second direction.

10. A system for processing semiconductor components, the system comprising:
a fixture, comprising:
a frame;
support surfaces, movably coupled to the frame, parallel to each other in a first direction, spaced apart from each other in a second direction, perpendicular to the first direction, and translationally movable relative to each other in the second direction to increase a pitch between adjacent support surfaces from a first pitch to a second pitch; and
flexible couplings, each between and fixed to respective adjacent ones of the support surfaces, wherein flexible couplings flex as the support surfaces translationally move relative to each other in the second direction; and
a first tray, comprising receptacles having a fourth pitch between adjacent receptacles, the fourth pitch being equal to the second pitch, wherein the first tray is releasably coupleable to the frame.

11. The system according to claim 10, wherein the first tray further comprises first apertures each formed in a respective one of the receptacles.

12. The system according to claim 11, further comprising:
a first vacuum base, relasably coupleable to the first tray and comprising at least one fluid conduit communicatively coupled with the first apertures of the first tray when the first vacuum base is releasably coupled to the first tray; and
a vacuum, communicatively coupleable with the at least one fluid conduit of the first vacuum base and operable to draw air from the receptacles of the first tray via the first apertures of the first tray and the at least one fluid conduit of the first vacuum base when the vacuum is communicatively coupled with the at least one fluid conduit of the first vacuum base and the first vacuum base is releasably coupled to the first tray.

13. The system according to claim 12, further comprising a second tray comprising receptacles having a fifth pitch between adjacent receptacles, the fifth pitch being equal to the second pitch, wherein the second tray is releasably coupleable to the first tray.

14. The system according to claim 13, wherein:
the second tray further comprises second apertures each formed in a respective one of the receptacles of the second tray;
the system further comprises a second vacuum base, relasably coupleable to the second tray and comprising at least one fluid conduit communicatively coupled with the second apertures of the second tray when the second vacuum base is releasably coupled to the second tray; and
the vacuum is communicatively coupleable with the at least one fluid conduit of the second vacuum base and operable to draw air from the receptacles of the second tray via the second apertures of the second tray and the at least one fluid conduit of the second vacuum base when the vacuum is communicatively coupled with the at least one fluid conduit of the second vacuum base and the second vacuum base is releasably coupled to the second tray.

15. A method of processing semiconductor components, the method comprising:
coupling a row of semiconductor components on support surfaces, spaced at a first pitch between adjacent surfaces, such that the row of semiconductor components extends in a second direction and each semiconductor component of the row of adjoined semiconductor components is supported by a respective one of the support surfaces, wherein:
the semiconductor components of the row of semiconductor components are adjoined; and
the support surfaces are parallel to each other in a first direction, perpendicular to the second direction, and spaced apart from each other in the second direction;
disjoining semiconductor components of the row of semiconductor components while positioned on the support surfaces, at the first pitch, at locations coincident with gaps defined between the support surfaces; and
after disjoining the semiconductor components of the row of semiconductor components, translational) moving the support surfaces relative to each other in the second direction to increase a pitch between adjacent support surfaces from the first pitch to a second pitch.

16. The method according to claim 15, further comprising releasably locking the support surfaces in place at the second pitch by positioning a spacer in each of the gaps defined between the support surfaces.

17. The method according to claim 16, wherein positioning the spacer in each of the gaps defined between the support surfaces comprises separately positioning groupings of spacers in the gaps in sequence along the support surfaces in the second direction.

18. The method according to claim 15, further comprising
releasably coupling a first tray, comprising receptacles having the second pitch between adjacent receptacles, with the support surfaces, at the second pitch, such that each receptacle is aligned with a respective one of the semiconductor components in a fourth direction perpendicular to the first and second directions;
with the first tray releasably coupled with the support surfaces, washing the first tray, support surfaces, and semiconductor components to decouple the semiconductor components from the support surfaces; and
transferring each of the semiconductor components decoupled from the support surfaces to within respective receptacles of the first tray.

19. The method according to claim 18, further comprising:
applying negative pressure to the semiconductor components within the receptacles of the first tray to retain the semiconductor components within the receptacles of the first tray; and
while applying the negative pressure to the semiconductor components within the receptacles of the first tray, decoupling the support surfaces from the first tray.

20. The method according to claim 19, further comprising:
after decoupling the support surfaces from the first tray, releasably coupling a second tray, comprising receptacles having the second pitch between adjacent receptacles, with the first tray such that each semiconductor component within the receptacles of the first tray is aligned with a respective one of the receptacles of the second tray in a fifth direction opposite the fourth direction;
transferring the semiconductor components from within the receptacles of the first tray to within respective receptacles of the second tray;
applying negative pressure to the semiconductor components within the receptacles of the second tray to retain the semiconductor components within the receptacles of the second tray; and
while applying the negative pressure to the semiconductor components within the receptacles of the second tray, decoupling the first tray from the second tray.
